(19) United States
(12) Patent Application Publication
(10) Pub. No.: US 2004/0070025 A1
(43) Pub. Date: Apr. 15, 2004

(54) NROM memory cell

(76) Inventors: Boaz Eitan, Ra'anana (IL); Elard Stein Von Kamienski, Dresden (DE); Stephan Riedel, Dresden (DE); Assaf Shappir, Kiryat-Ono (IL)

Correspondence Address: LERNER AND GREENBERG, P.A., POST OFFICE BOX 2480, HOLLYWOOD, FL, 33022-2480, US

(21) Appl. No.: 10/426,523

(22) Filed: Apr. 30, 2003

(30) Foreign Application Priority Data
Apr. 30, 2002 (DE) 102 19 343.6

(51) Int. Cl. H01L 29/792

(52) U.S. Cl. 257/324

(57) ABSTRACT

An NROM memory cell is of a planar configuration without an additional oxidation being affected for the fabrication of the bit line oxide. The ONO layer is provided as a memory layer and is disposed with a uniform thickness on the semiconductor material of the source and drain regions and of the channel region, so that the ONO layer forms not only the gate dielectric, but also the insulation of the bit lines from the word lines or the gate electrode.

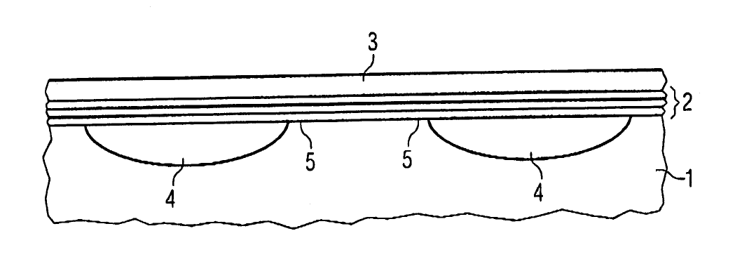

### BACKGROUND OF THE INVENTION

Field of the Invention

The present invention relates to a nitride read only memory (NROM) memory cell having an ONO memory layer.

The publication by B. Eitan et al., titled “NROM: A Novel Localized Trapping, 2-Bit Nonvolatile Memory Cell” in Electron Device Letters 21, 543-545 (2000), describes a memory cell in which doped regions as source and drain are formed at a distance from one another in a semiconductor body or a semiconductor layer. Situated on the top-side of the semiconductor material is a word line, which functions as a gate electrode above a channel region present between the regions of the source and the drain. Between the semiconductor material and the gate electrode, a memory layer containing a layer sequence composed of an oxide, a nitride and an oxide is situated as a gate dielectric and as memory medium. The memory layer is essentially limited to the channel region and regions of the source and the drain that adjoin the channel region. In order that the word line is electrically insulated from the doped regions of the source and the drain outside this region as well, regions made of an oxide, which may be fabricated e.g. by thermal oxidation of the semiconductor material, are in each case situated between the doped regions and the word line.

U.S. Pat. No. 6,133,095 describes a method for forming diffusion regions for the source and the drain in silicon by which it is possible to fabricate a memory cell structure similar to that described in the publication by Eitan cited above. To that end, first a nitride layer of the memory layer is bombarded with ions using a suitable mask technique, which ions pass into the nitride layer only in those regions in which a thick oxide layer is intended to be fabricated as a bit line oxide between the source or the drain and the word line disposed above, so that the nitride layer becomes porous at these locations. Afterward, both the porous silicon nitride layer and the portions of the silicon substrate that are present underneath are oxidized through the porous silicon nitride layer, thereby fabricating silicon oxynitride and silicon dioxide, respectively. The semiconductor material oxidized in this way forms thick oxide layers between the doped regions, provided as the source, the drain and bit lines, and the word line disposed above.

This configuration of the memory cell has the disadvantage that the thickness of the bit line oxide has to be precisely controlled during fabrication. Moreover, outdiffusion of the dopant from the doped regions occurs during the thermal oxidation, and this has been compensated for hitherto by enlarged dimensioning of the cell.

### SUMMARY OF THE INVENTION

It is accordingly an object of the invention to provide a NROM memory cell that overcomes the above-mentioned disadvantages of the prior art devices of this general type, which can be fabricated in a simple manner with smaller dimensions and smaller fault tolerances.

With the foregoing and other objects in view there is provided, in accordance with the invention, an NROM memory cell. The NROM memory cell contains a semiconductor body, doped regions for a source and a drain formed on the semiconductor body and disposed at a distance from one another, a channel region defined in the semiconductor body and disposed between the doped regions, a gate electrode disposed above the channel region between the doped regions, and a memory layer provided as a gate dielectric and as a memory medium. The memory layer is disposed between the gate electrode and the channel region. The memory layer has an oxide-nitride-oxide layer sequence and a bit line oxide for electrically insulating the doped regions from the gate electrode. The memory layer is disposed above the channel region and above the doped regions with a uniform thickness.

According to the invention, the NROM memory cell is of a planar configuration without an additional oxidation being affected for the fabrication of the bit line oxide. The ONO layer provided as the memory layer is disposed with uniform thickness on the semiconductor material, so that the ONO layer forms not only the gate dielectric, but also the insulation of the bit lines from the word lines or the gate electrode.

In accordance with an added feature of the invention, only the memory layer is present between a portion of the gate electrode or an associated word line and one of the doped regions.

In accordance with a further feature of the invention, the gate electrode is part of a word line of a memory cell configuration and each of the doped regions is part of a bit line of the memory cell configuration.

Other features which are considered as characteristic for the invention are set forth in the appended claims.

Although the invention is illustrated and described herein as embodied in a NROM memory cell, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

The single FIGURE of the drawing is a diagrammatic, section view of an exemplary embodiment of a NROM memory cell.

### DESCRIPTION OF THE PREFERRED EMBODIMENTS

Referring now in detail to the single FIGURE of the drawing, there is seen doped regions 4 for a source and a drain formed in a semiconductor body 1 or a semiconductor layer. A channel region 5 is situated between the doped regions 4. Above the channel region 5, a memory layer 2 is present as a gate dielectric and as a memory medium, which memory layer forms an oxide-nitride-oxide layer sequence (ONO). Situated above the latter is a gate electrode 3, which is patterned in the direction from source to drain, i.e. parallel to the plane of the drawing, in a strip-type manner to form a respective word line. Further portions of the memory layer 2 are situated between the doped regions 4 and the relevant portions of the gate electrode 3 or word line, the memory 2 layer being applied with uniform thickness over the whole area. Above the doped regions 4, the memory layer 2 forms an insulation which functions as bit line oxide. In the case of a configuration of a plurality of memory cells in a memory cell matrix, the bit lines run in the direction perpendicular to the plane of the drawing and electrically conductively connect the source/drain regions of the individual memory cells of a column to one another.

The advantages of the configuration of the NROM memory cell are:

a) a better control of the production tolerances during fabrication;

b) a possible reduction of the memory cell dimensions on account of a reduction of the thermal budget;

c) a better controllability of the channel of the cell; and

d) an increased erasing and programming speed, as has been established in a test that has already been carried out on silicon.

We claim:

1. An NROM memory cell, comprising:
a semiconductor body;
doped regions for a source and a drain formed on said semiconductor body and disposed at a distance from one another;
a channel region defined in said semiconductor body and disposed between said doped regions;
a gate electrode disposed above said channel region between said doped regions; and
a memory layer provided as a gate dielectric and as a memory medium, said memory layer disposed between said gate electrode and said channel region, said memory layer having an oxide-nitride-oxide layer sequence and
a bit line oxide for electrically insulating said doped regions from said gate electrode, said memory layer disposed above said channel region and above said doped regions with a uniform thickness.

2. The NROM memory cell according to claim 1, wherein only said memory layer is present between a portion of said gate electrode and one of said doped regions.

3. The NROM memory cell according to claim 1, wherein said gate electrode is part of a word line of a memory cell configuration and each of said doped regions is part of a bit line of the memory cell configuration.

4. The NROM memory cell according to claim 1, wherein said gate electrode is part of a word line of a memory cell configuration and only said memory layer is present between a portion of said word line and one of said doped regions.
